(19) United States
(12) Patent Application Publication
(10) Pub. No.: US 2022/0405225 A1
(43) Pub. Date: Dec. 22, 2022

(54) DEVICES TO SELECT STORAGE DEVICE PROTOCOLS

(71) Applicant: HEWLETT-PACKARD DEVELOPMENT COMPANY, L.P., Spring, TX (US)

(72) Inventors: Cody Allan RAVENSCROFT, Boise, ID (US); Hung-Ren WU, Boise, ID (US)

(21) Appl. No.: 17/777,205

(22) PCT Filed: Nov. 18, 2019
(86) PCT No.: PCT/US2019/061997

§ 371 Date: May 16, 2022

(51) Int. Cl. G06F 13/40; H03K 19/017

(52) U.S. Cl. CPC G06F 13/4022; G06F 13/4068; G06F 13/409; H03K 19/01742

(57) ABSTRACT

An example adapter device includes a host-side connector to connect to a host device, the host-side connector including a host-side electrical contact to connect to a corresponding electrical contact of the host device. The adapter device further includes a storage-side connector to connect to storage devices operable under different protocols, the storage-side connector including a storage-side electrical contact to connect to a connected storage device. The adapter device further includes a circuit to apply a bias voltage to the host-side electrical contact. The host-side electrical contact is to provide a protocol-indicating voltage to indicate to the host device a protocol of the connected storage device. The protocol-indicating voltage is dependent on the connected storage device's influence on the bias voltage.

### BACKGROUND

A variety of storage devices are available for use with computing devices and other electronic devices. Examples of storage devices include a hard disk drive (HDD) and a solid-state drive (SSD). Storage devices may be operable according to various protocols that govern the transfer of data between the storage device and a host device.

### BRIEF DESCRIPTION OF THE DRAWINGS

FIG. 1 is a schematic diagram of an example adapter device to provide a protocol-indicating voltage to a host device, the protocol-indicating voltage being dependent on a storage device connected to the adapter device.

FIG. 2 is a schematic diagram of an example adapter device with a pull-up resistor and an example host device with a pull-down resistor to bias a protocol-indicating voltage depending on a storage device connected to the adapter device or directly connected to the host device.

FIG. 3 is a schematic diagram of an example adapter device with a pull-down resistor and an example host device with a pull-up resistor to bias a protocol-indicating voltage depending on a storage device connected to the adapter device or directly connected to the host device.

FIG. 4 is a perspective diagram of an example host device as a riser circuit board with an example adapter device to provide a protocol-indicating voltage to the host device, the protocol-indicating voltage being dependent on a storage device connected to the adapter device.

### DETAILED DESCRIPTION

Detecting a protocol used by a storage device may use significant firmware, hardware, and/or processing resources. Protocol detection may also be made more complicated due to physical size differences among different storage devices and/or different arrangements of electrical contacts or pins.

A host device, such as a computer, printer, or riser board thereof, includes a multiplexer to select a data transfer protocol based on a signal received from a device connected to the host device. The connected device may be a storage device, such as an HDD, or may be an adapter that carries a different storage device, such as an SSD.

The adapter may include a pull-up resistor that provides a signal (high or low) to the host device depending on the protocol supported by a storage device, e.g., an SSD, connected to the host device through the adaptor. The host device may include a pull-down resistor that provides a low signal when the adapter is not connected, which may occur when a storage device, e.g., an HDD, is directly connected to the host device. The interaction of the pull-up and pull-down resistors allows for a set of protocols to be supported for storage devices used with and without the adaptor. The pull-up/pull-down logic can be inverted.

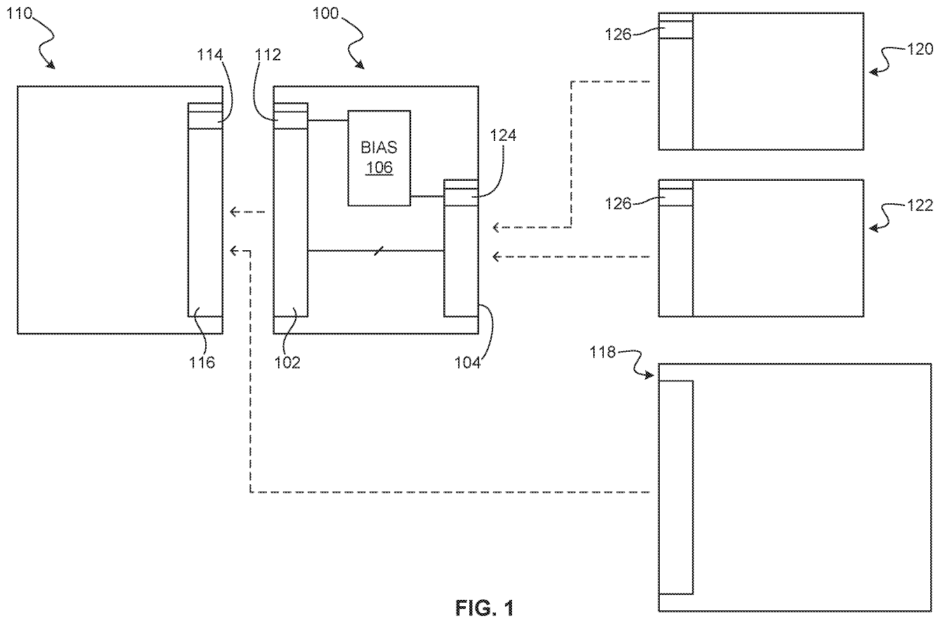

FIG. 1 shows an example adapter device 100. The adapter device 100 may be used during manufacture of a device such as a printer, computer, or similar host device 110 that is to store information. The adapter device 100 may be used by information technology (IT) staff or an end user when configuring such a host device. The adapter device 100 is used to connect a storage device to the host device. A storage device may be internal or external to the host device. The adapter device 100 and host device 110 may be considered a system when provided together or when connected. Other components provided with or connected to the adapter device 100 and/or host device 110 may be considered part of the same system.

The adapter device 100 includes a host-side connector 102, a storage-side connector 104, and a circuit 106.

The host-side connector 102 is to connect to a host device 110 that supports multiple different protocols for data transfer with various storage devices.

The host-side connector 102 includes a host-side electrical contact 112 to connect to a corresponding electrical contact 114 of the host device 110. The host-side electrical contact 112 is used to signal to the host device 110 a protocol to be used for data transfer.

The host-side connector 102 at the adaptor device 100 and a corresponding storage-side connector 116, which contains the contact 114, at the host device 110 may conform to a Serial Attached Small Computer System Interface (SAS), Serial Advanced Technology Attachment (SATA), or similar interface. As such, the contacts 112, 114 may be configured to communicate according to a SAS or SATA protocol or similar protocol. Further, when the adaptor device 100 is not connected to the host device 110, an independent storage device 118 that does not use the adapter device 100, such as a SATA HDD, may be directly connected to the storage-side connector 116 of the host device 110.

The storage-side connector 104 of the adaptor device 100 is to connect to storage devices 120, 122 operable under different protocols. The storage-side connector 104 communicates signals with the host-side connector 102 to facilitate data transfer between the host device 110 and a storage device 120, 122 connected to the storage-side connector 104.

The storage-side connector 104 includes a storage-side electrical contact 124 to electrically connect to the connected storage device 120, 122. The storage device 120, 122 may have a corresponding contact 126 that provides a signal to the storage-side electrical contact 124 to indicate the protocol used by the storage device 120, 122. The storage device 120, 122 may lack such as contact, in which case the signal at the storage-side electrical contact 124 would not be influenced by the storage device 120, 122. The signal (or lack thereof) received at the storage-side connector 104 may be used to indicate to the host device 110, via the host-side electrical contact 112, which protocol the host device 110 is to use for data transfer with the connected storage device 120, 122.

The storage-side connector 104 may be an M.2 connector or similar connector. The different protocols supported by storage devices 120, 122 may include a Peripheral Component Interconnect Express (PCIe) protocol and a SATA protocol. In many examples, a given storage device 120, 122 uses one of the different protocols, that is, either PCIe or SATA.

The circuit 106 connects the storage-side electrical contact 124 to the host-side electrical contact 112. The circuit 106 applies a bias voltage to the electrical contacts 112, 124. The signal at the host-side electrical contact 112 depends on the influence, if any, of a storage device 120, 122 connected the storage-side connector 104 and its electrical contact 124. That is, a connected storage device 120, 122 may pull against the bias voltage, via the electrical contact 124, or may not affect the bias voltage. A storage device 120, 122 may have its corresponding contact 126 set to indicate a protocol usable with the storage device 120, 122. Accordingly, the host device 110 may recognize a voltage at the electrical contact 114 as indicative of the protocol of a storage device 120, 122 connected through the adapter device 100. Hence, the host-side electrical contact 112 of the adapter device 100 provides a protocol-indicating voltage to indicate to the host device 110 a protocol of the connected storage device 120, 122. The protocol-indicating voltage is dependent on the connected storage device's influence on the bias voltage.

For example, the circuit 106 may provide a high bias voltage (e.g., 3.3 V) at the electrical contacts 112, 124. A storage device 120 that uses a SATA protocol may have its protocol-indicating contact 126 connected to ground. A storage device 122 that uses a PCIe protocol may have its protocol-indicating contact 126 unconnected, missing, or left to float. Thus, connection of the SATA storage device 120 to the adapter device 100 grounds the electrical contacts 112, 124, while connection of the PCIe storage device 122 to the adapter device 100 allows the electrical contacts 112, 124 to remain high. The host device 110 may select a SATA protocol for data transfer when detecting a low/ground level at its electrical contact 114. Conversely, the host device 110 may select a PCIe protocol for data transfer when detecting a high level at its electrical contact 114. Further, a storage device 118 that does not use the adapter device 100 may ground the electrical contact 114 of the host device 110, so as to indicate that a SATA protocol is to be used. In other examples, the levels may be reversed or different. Further, in various examples, the protocols may be varied or different.

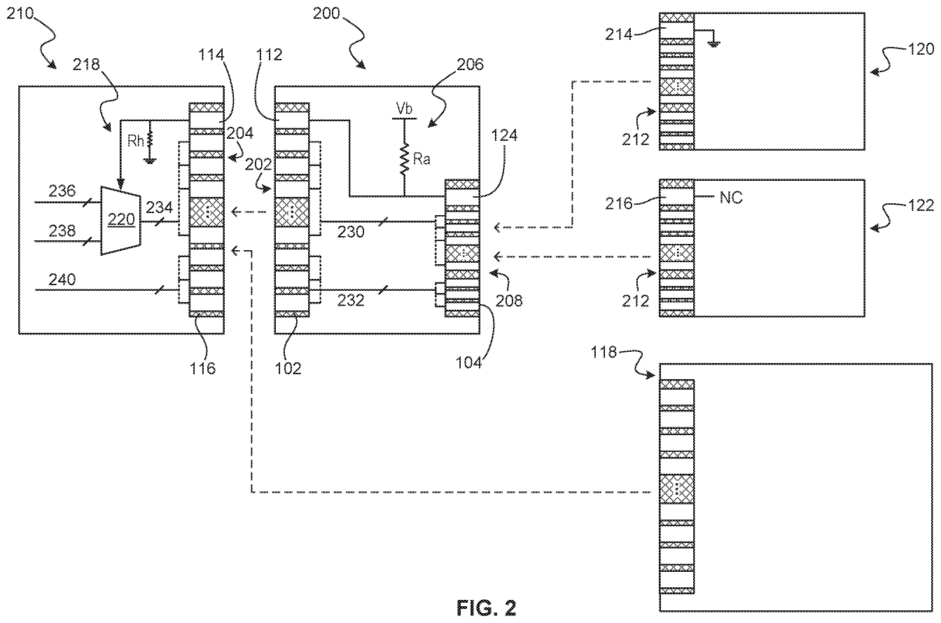

FIG. 2 shows an example adapter device 200 and an example host device 210. The adapter device 200 and host device 210 are similar to the other respective devices discussed herein, and only differences will be discussed in detail. Like reference numerals and/or terminology denotes like components.

The adapter device 200 includes a host-side connector 102 that includes a set of electrical contacts 202 to connect to a corresponding set of electrical contacts 204 of a storage-side connector 116 at the host device 210. The set of electrical contacts 202 may include data transfer contacts and operational contacts that connect to corresponding contacts at the host device 210. Data transfer contacts may be for the adapter device 200 to transmit and receive data to and from the host device 210 according to a selected protocol. Operational contacts may be for communication of clock signals, clock request signals, and similar operational signals between the adapter device 200 and the host device 210. Operational signals may also conform to the selected protocol. Each protocol-indicating contact 112, 114 may be considered to belong to the respective sets of contacts 202, 204.

The adapter device 200 includes a storage-side connector 104 that includes a set of electrical contacts 208 to connect to a corresponding set of electrical contacts 212 at each storage device 120, 122. The set of electrical contacts 208 may include data transfer contacts and operational contacts that connect to corresponding contacts at the storage devices 120, 122. Note that various storage devices 120, 122 may have more or fewer contacts as compared to the contacts 208 at the adaptor device 200. It is contemplated that a storage device 120, 122 may be designed to physically fit to the storage-side connector 104, and in such examples any additional or missing contacts would not be used for data transfer or operations with the adapter device 200.

Data transfer contacts of the set of contacts 208 may be for the adapter device 200 to transmit and receive data to and from a connected storage device 120, 122 according to a protocol supported by the storage device 120, 122. Operational contacts may be for communication of clock signals, clock request signals, and similar operational signals between the adapter device 200 and the connected storage device 120, 122. A protocol-indicating contact 124 of the adapter device 200 may be considered to belong to the set of contacts 208. Each storage device 120, 122 may include a respective protocol-indicating contact 214, 216 that may be considered part of the set of contacts 212.

Data transfer conductors (e.g., conductive traces) 230 may connect respective data transfer contacts of the sets of contacts 202, 208. Operational conductors 232 may connect respective operational contacts of the sets of contacts 202, 208. Any suitable number and arrangement of conductors 230, 232 and contacts 202, 208 may be provided, as may be dependent on the physical connections and protocols implemented.

The adapter device 200 includes a circuit 206 to detect a protocol supported by a connected storage device 120, 122 based on a loading (or lack thereof) at the protocol-indicating contact 124. The circuit 206 includes a high bias voltage Vb (e.g., 3.3 V) connected to the storage-side and host-side protocol-indicating contacts 124, 112 through a resistor Ra. The bias voltage Vb may be provided to the adapter device 200 by the host device 210 through respective power contacts of the set of contacts 202, 204. A such, if a protocol-indicating contact 214 of a storage device 120 is connected to ground internal to the storage device 120, then a protocol-indicating voltage at the contacts 124, 112 of the adapter device 200 is pulled low. Conversely, if a protocol-indicating contact 216 of a storage device 122 is missing, not connected (NC), or left to float at the storage device 120, then a protocol-indicating voltage at the contacts 124, 112 of the adapter device 200 is not pulled low and remains biased high by the circuit 206. Hence, a protocol-indicating voltage is available at the contact 112 to indicate to the host device 210 that a first or second protocol is to be used with the storage device 120, depending on whether the protocol-indicating voltage is low or high.

Grounding of a protocol-indicating contact 214 of a storage device 120 may be facilitated by grounding to the host device 210 via ground contacts of the sets of contacts 202, 204, 208, 212.

The host device 210 includes a bias circuit 218 and a connected multiplexer 220 to switch among data transfer protocols indicated by the adapter device 200 and connected storage device 120, 122 or a storage device 118 that does not use the adapter device 200.

The circuit 218 is connected to the storage-side contact 114 to detect the protocol indicated by the protocol-indicating contact 112 of the adapter device 200, and thus the protocol supported by the connected storage device 120, 122, or the independent storage device 118. The circuit 218 applies a bias voltage to the selection input of the multiplexer 220.

The multiplexer 220 is connected to the storage-side connector 116 to communicate data signals with a connected independent storage device 118 or the storage-device adapter 200. A protocol for data transfer is selectable by a selection input of the multiplexer 220. The multiplexer 220 selectively connects data transfer conductors 234 connected to respective data transfer contacts of the set of contacts 204 to first protocol conductors 236 and second protocol conductors 238 that may connect to protocol-specific components.

Operational conductors 240 connected to respective operational contacts of the set of contacts 204 may bypass the multiplexer 220. Any suitable number and arrangement of conductors 236, 238, 240 and contacts 204 may be provided, as may be dependent on the physical connections and protocols implemented.

The selection input of the multiplexer 220 and the storage-side contact 114 are mutually connected and grounded through a resistor Rh of the circuit 218. The circuit 218 thereby applies a low bias to the selection input of the multiplexer 220.

The resistance of the pull-down host resistor Rh may be selected to be greater than the resistance of the pull-up adapter resistor Ra, so that selection input of the multiplexer 220 is pulled high when no other influence is provided. That is, level of protocol-indicating voltage at storage-side electrical contact 114 tends towards a high level provided by the pull-up adapter resistor Ra when the adaptor device 200 is connected (without pull-low influence of a storage device 120, 122). When the adaptor device 200 is not connected, the level of protocol-indicating voltage at storage-side electrical contact 114 tends to low/ground provided by the pull-down host resistor Rh. Resistors Rh, Ra may be selected to provide suitable input levels to the selection input of the multiplexer 220, so that switching of the multiplexer 220 is unambiguous and does not unintentionally change due to poor connections, electrical noise, etc. In some examples, resistor Rh is 100 kΩ and resistor Ra is 1 kΩ, A ratio of Rh to Ra may be 1000:1, 100:1, 10:1, or similar so that the bias of the adaptor device 200 governs when the adaptor device 200 is connected.

The storage-side electrical contact 114 provides a protocol-indicating voltage to the selection input of the multiplexer 220 to indicate a protocol of a connected independent storage device 118 or a connected storage-device adapter 200. The protocol-indicating voltage is dependent on the connected storage device's or the connected storage-device adapter's influence on the bias voltage provided by the circuit 218. For example, a storage device 120 connected through the adapter device 200 provides a low voltage to the selection input of the multiplexer 220, thereby switching the multiplexer 220 to support a first data transfer protocol. Conversely, a storage device 122 connected through the adapter device 200 provides a high voltage to the selection input of the multiplexer 220, due to pull-up resistor Ra, thereby switching the multiplexer 220 to support a second data transfer protocol.

An independent storage device 118 may lack a contact to connect to the storage-side electrical contact 114 of the host device 210 or such contact may be grounded. As such, connecting the independent storage device 118 to the host device 210 (without the adapter device 200) results in the multiplexer 220 switching to support the first data transfer protocol, due to influence of the pull-down resistor Rh.

Table 1 summarizes example protocol-indicating signals at the selection input of the multiplexer 220 based on the device or devices connected to the storage-side connector 116 of the host device 210.

TABLE 1

| Device(s) | Protocol-indicating Signal |
|---|---|
| Adapter 200 with storage device (GND) | low |
| Adapter 200 with storage device (NC) | high |
| Storage device 118 without adapter | low |

In various examples, the multiplexer 220 selects between a SATA protocol (first protocol) and a PCIe protocol (second protocol). A storage device 120 that uses the adaptor device 200 and that supports the SATA protocol has its protocol-indicating contact 214 grounded or connected to a low voltage. Accordingly, the adapter device 200 triggers the multiplexer 220 to switch to the SATA protocol. A SATA storage device 118 that does not use the adaptor 200 may also trigger the multiplexer 220 to switch to the SATA protocol. A storage device 122 that uses the adaptor device 200 and that supports the PCIe protocol omits or does not connect the protocol-indicating contact 216 or allows such contact 216 to float. Accordingly, the adapter device 200 triggers the multiplexer 220 to switch to the PCIe protocol.

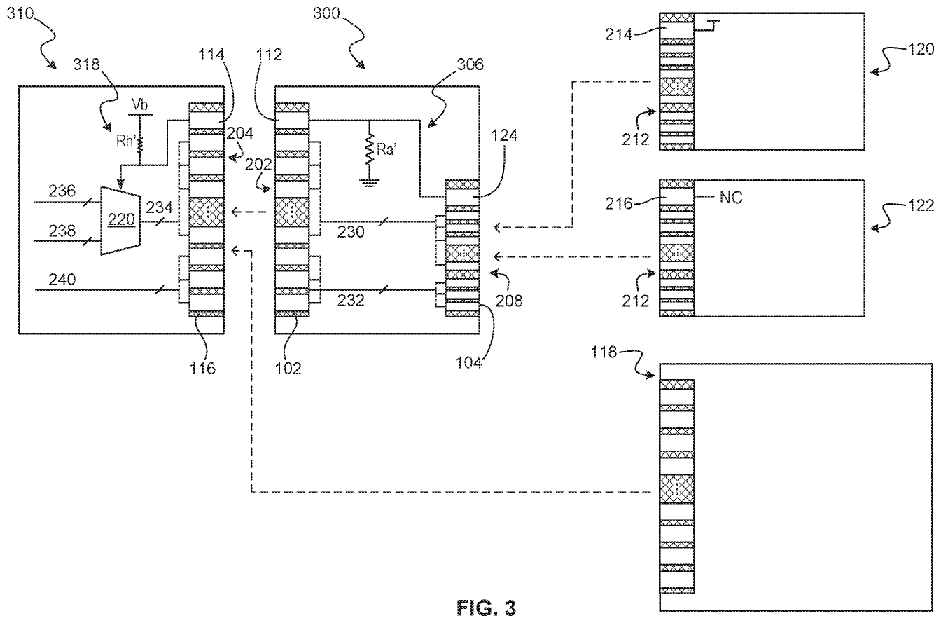

FIG. 3 shows an example adapter device 300 and an example host device 310. The adapter device 300 and host device 310 are similar to the other respective devices discussed herein, and only differences will be discussed in detail. Like reference numerals and/or terminology denotes like components.

The adapter device 300 includes a circuit 306 to detect a protocol supported by a connected storage device 120, 122 based on a loading (or lack thereof) at the protocol-indicating contact 124. The circuit 306 includes a resistor Ra′ that connects the storage-side and host-side protocol-indicating contacts 124, 112 to ground or other low voltage. Ground may be provided to the adapter device 300 by the host device 310 through respective ground contacts of the sets of contacts 202, 204. If a protocol-indicating contact 214 of a storage device 120 pulls sufficiently high against the low/ground bias, then a protocol-indicating voltage at the contacts 124, 112 of the adapter device 300 is pulled high. Conversely, if a protocol-indicating contact 216 of a storage device 122 is missing, not connected (NC), or left to float at the storage device 120, then a protocol-indicating voltage at the contacts 124, 112 of the adapter device 300 is not pulled high and remains biased low or to ground by the circuit 306. Hence, a protocol-indicating voltage is available at the contact 112 to indicate to the host device 310 that a first or second protocol is to be used with the storage device 120, depending on whether the protocol-indicating voltage is low or high.

The host device 310 includes a bias circuit 318 and a connected multiplexer 220 to switch among data transfer protocols indicated by the adapter device 300 and connected storage device 120, 122 or a storage device 118 that does not use the adapter device 300.

The circuit 318 is connected to the storage-side contact 114 to detect the protocol indicated by the protocol-indicating contact 112 of the adapter device 300, and thus the protocol supported by the connected storage device 120, 122, or the independent storage device 118. The circuit 318 applies a bias voltage to the selection input of the multiplexer 220.

The multiplexer 220 is connected to the storage-side connector 116 to communicate data signals with a connected independent storage device 118 or the storage-device adapter 300. A protocol for data transfer is selectable by a selection input of the multiplexer 220.

The selection input of the multiplexer 220 and the storage-side contact 114 are mutually connected to a bias voltage Vb (e.g., 3.3 V) through a resistor Rh′ of the circuit 318. The circuit 318 thereby applies a high bias to the selection input of the multiplexer 220. Accordingly, the selection input of the multiplexer 220 tends to be high unless the protocol-indicating contact 114 provides sufficient low bias or grounding.

Table 2 summarizes example protocol-indicating signals at the selection input of the multiplexer 220 based on the device or devices connected to the storage-side connector 116 of the host device 310.

TABLE 2

| Device(s) | Protocol-indicating Signal |
|---|---|
| Adapter 300 with storage device (high) | high |
| Adapter 300 with storage device (NC/GND) | low |
| Storage device 118 without adapter | high |

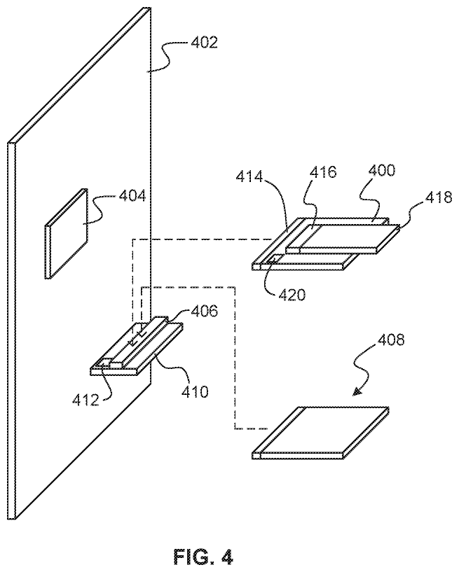

FIG. 4 shows an example adapter device 400 and an example host device 410. The adapter device 400 and host device 410 are similar to the other respective devices discussed herein, and only differences will be discussed in detail. Like reference numerals and/or terminology denotes like components.

The host device 410 may include a riser circuit board installable on a mainboard 402 or similar structure of a computer, printer, or similar electronic device. The mainboard 402 may further support a processor, memory, chipset, communications interface, and similar components, generally at 404, to provide functionality of the electronic device. The mainboard 402 may include a power supply that provides power and ground to the host device 410, adapter device 400, and any connected storage device.

The host device 410 may include a storage-side connector 406 to connect to the adapter device 400 or an independent storage device 408.

The host device 410 further includes a host bias circuit 412 to bias a protocol selection at the host device 410 to a first protocol. The bias circuit 412 selects the first protocol when the adapter device 400 is not connected or when the independent storage device 408 is connected.

The adapter device 400 includes a host-side connector 414 to connect to the host device 410 and a storage-side connector 416 to connect to a storage device 418. The adapter device 400 may also physically carry and secure the storage device 418.

The adapter device 400 includes an adapter bias circuit 420 to bias protocol selection at the host device 410 to a second protocol. The bias circuit 420 at the adapter device 400 provides a stronger bias than the bias circuit 412 at the host device 410. The bias circuit 420 accepts influence from a connected storage device 418. Thus, when the adapter device 400 is connected to the host device 410, the second protocol is selected unless the storage device 418 carried by the adapter device 400 reduces or nullifies the bias provided by the bias circuit 420. When a connected storage device 418 sufficiently reduces or nullifies the bias provided by the bias circuit 420, the bias circuit 412 at the host device 410 governs and the first protocol is selected. As such, the host device 410 and adapter device 400, if connected, operate to automatically select a protocol for the connected storage device 418, 408 without consuming processing/logical resources 404 of the mainboard 402.

The host and adapter bias circuits 412, 420 may include pull-up and pull-down resistors, as discussed elsewhere herein.

In view of the above, it should be apparent that various storage devices that have different physical connections may be useable with a given host device. An adapter device may be used with one type of physical connection (e.g., M.2 SSD) and may be omitted when a storage device uses another type of physical connection (e.g., SATA HDD). Further, the host and adapter devices may also provide low-complexity hardware-based protocol selection for storage devices that use the adapter, while the host device may provide the same, without modification, for storage devices that do not use the adapter.

It should be recognized that features and aspects of the various examples provided above can be combined into further examples that also fall within the scope of the present disclosure. In addition, the figures are not to scale and may have size and shape exaggerated for illustrative purposes.

1. An adapter device comprising:
a host-side connector to connect to a host device, the host-side connector including a host-side electrical contact to connect to a corresponding electrical contact of the host device;
a storage-side connector to connect to storage devices operable under different protocols, the storage-side connector including a storage-side electrical contact to connect to a connected storage device; and
a circuit to apply a bias voltage to the host-side electrical contact;
wherein the host-side electrical contact is to provide a protocol-indicating voltage to indicate to the host device a protocol of the connected storage device, the protocol-indicating voltage being dependent on the connected storage device's influence on the bias voltage.

2. The adapter device of claim 1, wherein:
the bias voltage is high;
the circuit includes a pull-up resistor;
the protocol-indicating voltage is to indicate a first protocol when the storage-side electrical contact pulls the protocol-indicating voltage low; and
the protocol-indicating voltage is to indicate a second protocol when the storage-side electrical contact does not pull the protocol-indicating voltage low.

3. The adapter device of claim 1, wherein:
the bias voltage is low;
the circuit includes a pull-down resistor;
the protocol-indicating voltage is to indicate a first protocol when the storage-side electrical contact does not pull the protocol-indicating voltage high; and
the protocol-indicating voltage is to indicate a second protocol when the storage-side electrical contact pulls the protocol-indicating voltage high.

4. The adapter device of claim 1, wherein the storage-side connector is an M.2 connector, and wherein the different protocols include a Peripheral Component Interconnect Express (PCIe) protocol and a Serial Advanced Technology Attachment (SATA) protocol.

5. A host device comprising:
a storage-side connector to connect to a storage device or a storage-device adapter, the storage-side connector including a storage-side electrical contact to connect to a corresponding electrical contact of the storage device or the storage-device adapter;
a multiplexer connected to the storage-side connector to communicate data signals with the storage device or the storage-device adapter according to a protocol that is selectable by a selection input of the multiplexer; and
a circuit connected to the storage-side electrical contact and the selection input of the multiplexer, the circuit to apply a bias voltage to the selection input;
wherein the storage-side electrical contact is to provide a protocol-indicating voltage to the selection input of the multiplexer to indicate a protocol of a connected storage device or a connected storage-device adapter, the protocol-indicating voltage being dependent on the connected storage device's or the connected storage-device adapter's influence on the bias voltage.

6. The host device of claim 5, wherein:
the bias voltage is low;
the circuit includes a pull-down resistor;
the protocol-indicating voltage is to indicate a first protocol when the storage-side electrical contact does not pull the protocol-indicating voltage high; and
the protocol-indicating voltage is to indicate a second protocol when the storage-side electrical contact pulls the protocol-indicating voltage high.

7. The host device of claim 5, wherein:
the bias voltage is high;
the circuit includes a pull-up resistor;
the protocol-indicating voltage is to indicate a first protocol when the storage-side electrical contact pulls the protocol-indicating voltage low; and
the protocol-indicating voltage is to indicate a second protocol when the storage-side electrical contact does not pull the protocol-indicating voltage low.

8. The host device of claim 5, further comprising a riser circuit board.

9. The host device of claim 5, wherein the storage-side connector is a Serial Attached Small Computer System Interface (SAS), and wherein the multiplexer is to select between a Peripheral Component Interconnect Express (PCIe) protocol and a Serial Advanced Technology Attachment (SATA) protocol.

10. A system comprising:
a host device including a storage-side connector and host bias circuit; and
an adapter device including a host-side connector and adapter bias circuit, the host-side connector to connect to the storage-side connector of the host device to electrically connect the adapter bias circuit to the host bias circuit, the adapter device further including a storage-side connector to connect to a storage device;
wherein the host bias circuit is to bias selection of a first data transfer protocol, and wherein the adapter bias circuit is to bias selection of a second data transfer protocol for the storage device.

11. The system of claim 10, wherein the host bias circuit includes a pull-down resistor and the adapter bias circuit includes a pull-up resistor.

12. The system of claim 10, wherein the host bias circuit includes a pull-up resistor and the adapter bias circuit includes a pull-down resistor.

13. The system of claim 10, wherein the storage device supports the first data transfer protocol and grounds the adapter bias circuit to select the first data transfer protocol at the host device.

14. The system of claim 10, wherein the storage device supports the second data transfer protocol and does not influence the adapter bias circuit, thereby selecting the second data transfer protocol at the host device.

15. The system of claim 10, wherein the storage-side connector of the host device is to connect to another storage device, wherein the host bias circuit is to bias selection of the first data transfer protocol for the other storage device.
